(19) United States
(12) Patent Application Publication
(10) Pub. No.: US 2024/0405048 A1
(43) Pub. Date: Dec. 5, 2024

(54) IMAGE SENSOR

(71) Applicant: Samsung Electronics Co., Ltd., Suwon-si (KR)

(72) Inventors: JUNSEOK KIM, Suwon-si (KR); KWANHEE LEE, Suwon-si (KR); MOOSUNG KWAK, Suwon-si (KR); CHULWOONG LEE, Suwon-si (KR); Gyubeom IM, Suwon-si (KR)

(21) Appl. No.: 18/539,377

(22) Filed: Dec. 14, 2023

(30) Foreign Application Priority Data
May 30, 2023 (KR) 10-2023-0069425

(51) Int. Cl. H01L 27/146

(52) U.S. Cl. CPC H01L 27/14634; H01L 27/14612; H01L 27/14636

(57) ABSTRACT

An embodiment of the present disclosure provides an image sensor including: a first die including a pixel array area in which first and second photoelectric conversion devices that generate respective charges corresponding to incident light are disposed; and a second die including a first pixel circuit that receives the charges from the first photoelectric conversion device and generates a phase signal of the incident light based on the charges received from the first photoelectric conversion device, and a second pixel circuit that receives the charges from the second photoelectric conversion device and generates an event signal corresponding to the incident light based on the charges received from the second photoelectric conversion device.

### CROSS-REFERENCE TO RELATED APPLICATION

This application claims priority to and the benefit under 35 U.S.C. § 119 of Korean Patent Application No. 10-2023-0069425, filed in the Korean Intellectual Property Office on May 30, 2023, the entire contents of which are incorporated herein by reference.

### BACKGROUND OF THE INVENTION

The present disclosure relates to an image sensor.

Typical examples of image sensors are complementary metal-oxide semiconductor (CMOS) image sensors and dynamic vision sensors (DVS). The CMOS image sensor has an advantage of providing a captured image to a user as it is, but has a disadvantage of a large amount of data to be processed. When an event (for example, change in light intensity) occurs, the dynamic vision sensor generates information about the event, that is, an event signal, and transmits the event signal to a processor, so an amount of data to be processed is small. When the event signals of the dynamic vision sensor are interlocked with the CMOS image sensor, it is possible to support various functions such as de-blur or super slow.

In addition, when the CMOS image sensor and the dynamic vision sensor are implemented as one image sensor, signals outputted from the CMOS image sensor and/or the dynamic vision sensor may be transmitted to and processed by an image signal processor (ISP). In this case, the image signal processor may perform processes such as bad pixel correction (BPC) on the signal outputted from the DVS pixel of the dynamic vision sensor.

On the other hand, the CMOS image sensor may provide a phase detection auto-focus (PDAF) function for focusing on an object in photographing the object, and phase detection pixels required to perform the phase detection auto focus (PDAF) may be discontinuously or regularly disposed within a pixel array.

### SUMMARY OF THE INVENTION

The present disclosure is to provide an image sensor that includes a phase detection pixel capable of detecting a phase difference for an object and a dynamic vision sensor pixel capable of detecting an event.

The present disclosure is to provide an image sensor that includes a semiconductor die in which a plurality of layers are stacked.

An embodiment of the present disclosure provides an image sensor including: a first die including a pixel array area in which first and second photoelectric conversion devices configured to generate respective charges corresponding to incident light are disposed; and a second die including a first pixel circuit configured to receive the charges from the first photoelectric conversion device and generate a phase signal of the incident light based on the charges received from the first photoelectric conversion device, and a second pixel circuit configured to receive the charges from the second photoelectric conversion device and generate an event signal corresponding to the incident light based on the charges received from the second photoelectric conversion device.

The image sensor may further include a third die including a first logic circuit configured to receive the phase signal from the first pixel circuit, a second logic circuit configured to receive the event signal from the second pixel circuit, and an image signal processor (ISP) configured to receive data outputted from the first logic circuit and the second logic circuit.

The image sensor may further include a first pad disposed on the first die to be spaced apart from the pixel array area, a second pad disposed on the second die to be spaced apart from the first pixel circuit and the second pixel circuit, and a third pad disposed on the third die to be spaced apart from the first logic circuit, the second logic circuit, and the image signal processor.

The first pad may be electrically connected to the second pad, and the second pad may be electrically connected to the third pad.

A third photoelectric conversion device configured to generate charges corresponding to incident light and a third pixel circuit configured to receive the charges from the third photoelectric conversion device to generate an output voltage may be further disposed in the pixel array area.

The third pixel circuit may be connected to the first pad through a metal layer on the first die.

The number of the first photoelectric conversion devices and the second photoelectric conversion devices with respect to the number of the third photoelectric conversion devices in the pixel array area may satisfy a predetermined ratio.

The image sensor may further include a first connection structure configured to connect the first photoelectric conversion device and the first pixel circuit and disposed in an area in which the pixel array area and the first pixel circuit overlap, and a second connection structure configured to connect the second photoelectric conversion device and the second pixel circuit and disposed in an area in which the pixel array area and the second pixel circuit overlap.

The image sensor may further include a first switch including one end electrically connected to the second connection structure and the other end electrically connected to the second pixel circuit, and a second switch including one end electrically connected between the first connection structure and the first pixel circuit and the other end electrically connected to one end of the first switch.

The first switch and the second switch may be disposed on the second die.

The first connection structure and the second connection structure may be at least one of an electrical line, a wire, a solder ball, a bump, and a through silicon via (TSV).

The first photoelectric conversion device and the second photoelectric conversion device may be disposed adjacent to each other, and one micro lens disposed on the first photoelectric conversion device and the second photoelectric conversion device may be further included.

The image sensor may further include a mask layer disposed on the first photoelectric conversion device and of which a first or second side is shielded.

Another embodiment of the present disclosure provides an image sensor including: a phase detection pixel including a first photoelectric conversion device configured to generate charges corresponding to incident light, and a first pixel circuit configured to generate an output voltage corresponding to the charges received from the first photoelectric conversion device and a phase signal of the incident light; and a dynamic vision sensor (DVS) pixel including a second photoelectric conversion device configured to generate charges corresponding to incident light, and a second pixel circuit configured to generate an event signal by detecting a change in intensity of the incident light based on the charges received from the second photoelectric conversion device.

The image sensor may further include a first logic circuit configured to receive the phase signal from the first pixel circuit, a second logic circuit configured to receive the event signal from the second pixel circuit, and an image signal processor (ISP) configured to receive data outputted from the first logic circuit and the second logic circuit.

The image signal processor may generate a signal that controls a first mode in which the first photoelectric conversion device is connected to the first pixel circuit and the second photoelectric conversion device is connected to the second pixel circuit, a second mode in which the first photoelectric conversion device is connected to the second pixel circuit, and a third mode in which the second photoelectric conversion device is connected to the first pixel circuit.

The image sensor may include a first switch disposed between the second photoelectric conversion device and the second pixel circuit and including one end electrically connected to the second photoelectric conversion device and the other end electrically connected to the second pixel circuit, and a second switch including one end electrically connected between the first photoelectric conversion device and the first pixel circuit and the other end electrically connected to one end of the first switch, wherein the image signal processor may switch on the first switch and may switch off the second switch in the first mode, the image signal processor may switch on the first switch and may switch on the second switch in the second mode, and the image signal processor may switch off the first switch and may switch on the second switch in the third mode.

The first photoelectric conversion device and the second photoelectric conversion device may be disposed on a semiconductor die different from a semiconductor die on which the first pixel circuit and the second pixel circuit are disposed.

The first pixel circuit and the second pixel circuit may be disposed on the same semiconductor die.

Another embodiment of the present disclosure provides an image sensor including: a first semiconductor die including a first photoelectric conversion device and a second photoelectric conversion device configured to convert an optical signal into an electrical signal, and a second semiconductor die that includes: a first pixel circuit that includes a first transistor configured to transmit the electrical signal received from the first photoelectric conversion device to a floating diffusion node, a second transistor having a gate electrode connected to the floating diffusion node, and a third transistor configured to reset the floating diffusion node, and a second pixel circuit that includes an output logic circuit configured to generate an event signal by detecting a change in intensity of an optical signal based on the electrical signal received from the second photoelectric conversion device.

### BRIEF DESCRIPTION OF THE DRAWINGS

FIG. 1 illustrates an image sensor according to an example embodiment.

FIG. 2 illustrates a perspective view of an image sensor according to an example embodiment.

FIG. 3 illustrates an example configuration of a CMOS image sensor.

FIGS. 4 to 7B illustrate top plan views of pixel disposition of a pixel array according to an example embodiment.

FIG. 8 illustrates a circuit diagram of an example configuration of a pixel according to an example embodiment.

FIG. 9 illustrates an example configuration of a dynamic vision sensor according to an example embodiment.

FIG. 10 illustrates a circuit diagram of an example configuration of a dynamic vision sensor pixel according to an example embodiment.

FIG. 11 illustrates an example configuration of a back-end circuit of a dynamic vision sensor pixel according to an example embodiment.

FIG. 12 and FIG. 13 illustrate top plan views of pixel disposition including a phase detection pixel and a dynamic vision sensor pixel according to an example embodiment.

FIG. 14 illustrates a perspective view of an image sensor according to an example embodiment.

FIG. 15 illustrates a circuit diagram of an example configuration of a portion of an image sensor according to an example embodiment.

FIG. 16 illustrates a top plan view of pixel disposition including a phase detection pixel and a dynamic vision sensor pixel according to an example embodiment.

FIG. 17 illustrates a perspective view of an image sensor according to an example embodiment.

FIG. 18 illustrates a circuit diagram of an example configuration of a portion of an image sensor according to an example embodiment.

FIG. 19 and FIG. 20 illustrate circuit diagrams of an example configuration of a portion of an image sensor according to an example embodiment.

FIG. 21 illustrates a block diagram of a computing device according to an example embodiment.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Accordingly, the drawings and description are to be regarded as illustrative in nature and not restrictive, and like reference characters designate like elements throughout the specification and drawings.

In addition, a singular form may be intended to include a plural form as well, unless an explicit expression such as “one” or “single” is used. Terms including ordinal numbers such as first, second, and the like will be used only to describe various constituent elements, and are not to be interpreted as limiting these constituent elements. These terms may be used for a purpose of distinguishing one constituent element from other constituent elements.

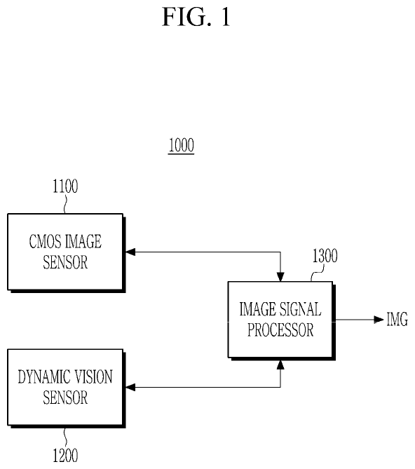

FIG. 1 illustrates an image sensor 1000 according to an example embodiment of the present disclosure. The image sensor 1000 may include a complementary metal oxide semiconductor (CMOS) image sensor 1100, a dynamic vision sensor (DVS) 1200, and an image signal processor 1300.

The CMOS image sensor 1100 and the dynamic vision sensor 1200 each may include a plurality of pixels each including a photoelectric conversion device (PSD), but are not limited thereto.

The image signal processor 1300 may process data outputted from the CMOS image sensor 1100 and/or the dynamic vision sensor 1200 to generate an image (IMG). In the embodiment, the image signal processor 1300 may process frame-based image data received from the CMOS image sensor 1100 to generate an image (IMG). In addition, the image signal processor 1300 may process packet-based or frame-based image data received from the dynamic vision sensor 1200 to generate an image (IMG).

The image signal processor 1300 may perform various processes on image data received from the CMOS image sensor 1100. For example, the image signal processor 1300 may perform various processing such as color interpolation, color correction, auto white balance, gamma correction, color saturation correction, formatting, bad pixel correction, and hue correction.

The image signal processor 1300 may perform various processes on image data received from the dynamic vision sensor 1200. For example, the image signal processor 1300 may correct timestamp values of noise pixels, hot pixels, or dead pixels by using temporal correlation of timestamp values of adjacent pixels configuring the dynamic vision sensor 1200.

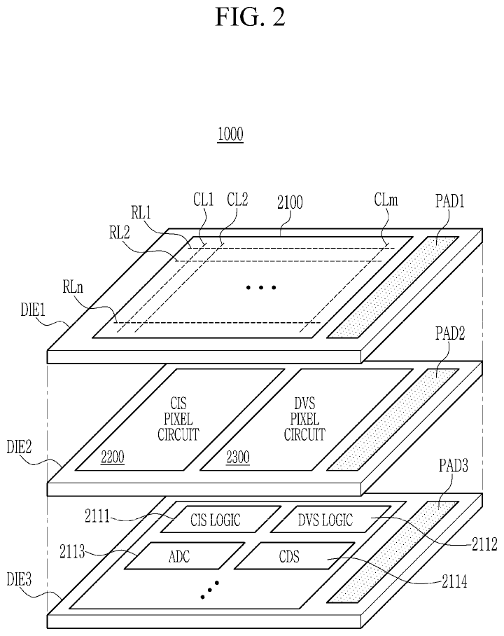

FIG. 2 illustrates a perspective view of an image sensor according to an example embodiment.

Referring to FIG. 1 and FIG. 2, the image sensor 1000 may be formed by stacking three layers. For example, the image sensor 1000 may include first to third semiconductor dies DIE1 to DIE3. The first to third semiconductor dies DIE1 to DIE3 may be manufactured using different semiconductor processes or different semiconductor wafers.

The first semiconductor die DIE1 may include a pixel array area 2100. The pixel array area 2100 may include a plurality of row lines (RL1, RL2, . . . , RLn) and a plurality of column lines (CL1, CL2, . . . , CLm), and a plurality of pixels that are connected to N row lines and M column lines and disposed in a matrix form may be disposed in the pixel array. In the embodiment, a plurality of image sensing pixels IPX, a photoelectric conversion device (PSD) of a phase detection pixel, and a photoelectric conversion device (PSD) of a DVS pixel may be disposed within the pixel array of the first semiconductor die DIE1.

In addition, the first semiconductor die DIE1 may include a first pad area PAD1. The pixel array area 2100 and the first pad area PAD1 can be physically separated from each other or spaced apart from each other by a predetermined distance. The first pad area PAD1 may be an area for forming a plurality of pads configured to be connected to a second pad area PAD2 of the second semiconductor die DIE2 and a third pad area PAD3 of the third semiconductor die DIE3. The first pad area PAD1 may be connected to elements of the pixel array area 2100 through a metal layer formed on the first semiconductor die DIE1.

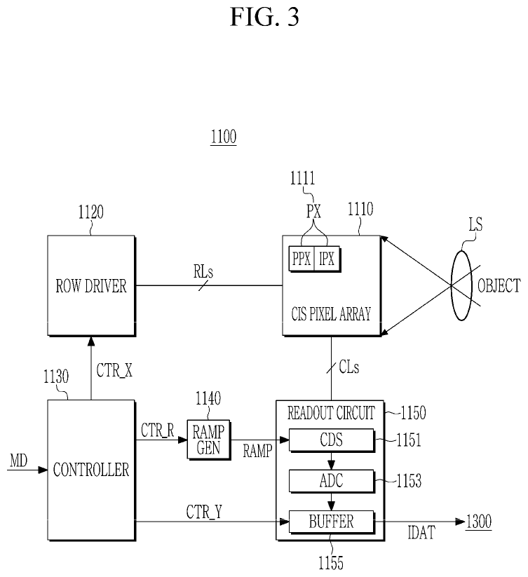

The second semiconductor die DIE2 may include a CMOS image sensor (CIS) pixel circuit 2200 and a DVS pixel circuit 2300. In the embodiment, the CIS pixel circuit 2200 may include a pixel circuit for a phase detection pixel, and the DVS pixel circuit 2300 may include a DVS pixel back-end circuit and the like. The CIS pixel circuit 2200 and the DVS pixel circuit 2300 will be described in detail with reference to FIG. 3 to FIG. 11.

In addition, the second semiconductor die DIE2 may further include the second pad area PAD2. The CIS pixel circuit 2200 and the DVS pixel circuit 2300 and the second pad area PAD2 may be physically separated from each other or spaced apart from each other by a predetermined distance. The second pad area PAD2 may be an area for forming a plurality of pads configured to be connected to the first pad area PAD1 of the first semiconductor die DIE1 and the third pad area PAD3 of the third semiconductor die DIE3. The second pad area PAD2 may be connected to the CIS pixel circuit 2200 and the DVS pixel circuit 2300 through a metal layer formed on the second semiconductor die DIE2.

The third semiconductor die DIE3 may include remaining constituent elements of the image sensor 1000 that are not formed on the first semiconductor die DIE1 and the second semiconductor die DIE2. For example, a CIS logic 2111, a DVS logic 2112, an analog to digital converter (ADC) 2113, a correlated-double sampler (CDS) 2114, and the like may be included. Although not shown, the third semiconductor die DIE3 may further include an image signal processor (ISP) and the like. Respective constituent elements will be described in detail with reference to FIG. 3 to FIG. 11.

In addition, the third semiconductor die DIE3 may further include the third pad area PAD3. The CIS logic 2111, the DVS logic 2112, and the like and the third pad area PAD3 may be physically separated from each other or spaced apart from each other by predetermined distances. The third pad area PAD3 may be an area for forming a plurality of pads configured to be connected to the first pad area PAD1 of the first semiconductor die DIE1 and the second pad area PAD2 of the second semiconductor die DIE2. The third pad area PAD3 may be connected to the CIS logic 2111, the DVS logic 2112, and the like through a metal layer formed on the third semiconductor die DIE3.

Although not shown in the present specification, the first, second, and third semiconductor dies DIE1, DIE2, and DIE3 may be respectively connected to the first and second pad areas PAD1 and PAD2 and may be connected by using connection structures that are connected to the second and third pad areas PAD2 and PAD3, and the connection structures may be at least one of electrical lines, wires, solder balls, bumps, and through silicon vias (TSV), but are not limited thereto.

As described, in the image sensor 1000 including both CIS pixels and DVS pixels, the structure in which the CIS pixels and the DVS pixel circuit 2300 are formed on separate semiconductor dies may optimize the size of the image sensor 1000. In addition, by further implementing the CIS pixel circuit 2200 in the semiconductor die DIE2 in which the DVS pixel circuit 2300 is formed, the space of the semiconductor die DIE2 may be efficiently utilized. In the embodiment, the CIS pixel circuit 2200 implemented on the same semiconductor die DIE2 as the DVS pixel circuit 2300 may be a pixel circuit for phase detection auto focus.

FIG. 3 illustrates an example configuration of a CMOS image sensor according to an example embodiment.

Referring to FIG. 3, the CMOS image sensor 1100 may include a lens LS, a pixel array 1110, a row driver 1120, a controller 1130, a ramp generator 1140, and a readout circuit 1150.

The CMOS image sensor 1100 may convert an optical signal of an object (OBJECT) incident through an optical device into an electrical signal, and may generate image data IDAT based on the converted electrical signal. The optical device may be an optical concentrating device including a mirror and the lens LS, but is not limited thereto, and the CMOS image sensor 1100 may use various optical devices.

The pixel array 1110 may include a plurality of pixels PX (also referred to herein as pixels 1111), and a plurality of row lines RLs and a plurality of column lines CLs respectively connected to the plurality of pixels PX.

The row lines RL may extend in a first direction, and may be connected to the pixels PX disposed along the first direction. For example, the row lines RL may transmit a control signal outputted from the row driver 1120 to an element included in the pixel PX, for example, a transistor. The column lines CL may extend in a second direction crossing the first direction, and may be connected to the pixels PX disposed along the second direction. The column lines CL may transmit a pixel signal outputted from the pixels PX to the readout circuit 1150.

The plurality of pixels PX included in the pixel array 1110 may include a plurality of image sensing pixels IPX and a plurality of phase detection pixels PPX.

The plurality of image sensing pixels IPX may generate image signals corresponding to the object (OBJECT). The plurality of phase detection pixels PPX may not only generate an image signal corresponding to the object (OBJECT), but may further generate phase signals used to focus on the object (OBJECT). The phase signals may include information on positions of an image corresponding to the object (OBJECT) incident through an optical device. An image signal and a phase signal generated by the plurality of image sensing pixels IPX and the plurality of phase detection pixels PPX may be transmitted to the readout circuit 1150 through the column lines CL. The readout circuit 1150 may calculate a phase difference between images through the phase signal.

The row driver 1120 may generate a control signal for driving the pixel array 1110 in response to a control signal of the controller 1130 (for example, a row control signal CTR_X), and may provide the control signal to the plurality of pixels PX of the pixel array 1110 through the plurality of row lines RL.

The controller 1130 may generally control each of the constituent elements 1110, 1120, 1140, and 1150 included in the CMOS image sensor 1100. The controller 1130 may control an operation timing of each of the constituent elements 1110, 1120, 1140, and 1150 by using control signals. For example, the controller 1130 may provide the row control signal CTR_X to the row driver 1120, and the row driver 1120, based on the row control signal CTR_X, may control the pixel array 1110 to be sensed in units of row lines through the row lines RL. For example, the controller 1130 may provide a ramp control signal CTR_R for controlling a ramp signal to the ramp generator 1140, and the ramp generator 1140 may generate a reference signal RAMP for an operation of the readout circuit 1150 based on the ramp control signal CTR_R. For example, the controller 1130 may provide a column control signal CTR_Y to the readout circuit 1150, and the readout circuit 1150 may receive and process a pixel signal from the pixel array 1110 through the column lines CL based on the column control signal CTR_Y.

The readout circuit 1150 may convert a pixel signal (or an electrical signal) from the pixels PXs connected to the row lines RL selected from the plurality of pixels PX according to the control from the controller 1130 into a pixel value indicating an amount of light. The readout circuit 1150 may process the pixel signal outputted through the corresponding column line CL to output it as the image data IDAT. The readout circuit 150 may include a correlated double sampling (CDS) circuit 1151, an analog-to-digital converter (ADC) circuit 1153, and a buffer 1155.

The correlated double sampling circuit 1151 may include a plurality of comparators, and each of the comparators may compare the pixel signal received from the pixel array 1110 through the plurality of column lines CL with the reference signal RAMP from the ramp generator 1140 to output the comparison result to the analog-to-digital converter circuit 1153. In addition, the correlated double sampling circuit 1151 may receive a phase signal from the pixel array 1110 to perform a phase difference operation. For example, the CDS circuit 1151 may perform a correlated double sampling operation on the phase signal received from the phase detection pixel PPX to obtain a focus position, a focus direction, or a distance between the object (OBJECT) and the CMOS image sensor 1100. Thereafter, the controller 1130 may output a control signal for moving the position of the lens LS based on the result of the correlated double sampling operation.

The analog-to-digital converter circuit 1153 converts the comparison result of the correlated double sampling circuit 1151 into digital data, thereby generating and outputting pixel values corresponding to a plurality of pixels in row units. The analog-to-digital converter circuit 1153 may include a plurality of counters, and the plurality of counters may be respectively connected to outputs of the plurality of comparators, and may count comparison results outputted from the comparators, thereby outputting digital data (for example, pixel values) according to the counting results.

The buffer 1155 may store a pixel value outputted from the analog-to-digital converter circuit 1153, respectively. The buffer 1155 may store digital data for each row. In the embodiments, the buffer 1155 may temporarily store a plurality of digital data outputted from the counter, then amplify and output them. For example, the buffer 1155 may be an output buffer. The buffer 1155 may output the image data IDAT amplified based on the column control signal CTR_Y of the controller 1130 to the outside.

In the embodiment, at least some of the aforementioned row driver 1120, the controller 1130, the ramp generator 1140, and the readout circuit 1150 may be the CIS logic 2111 shown in FIG. 2.

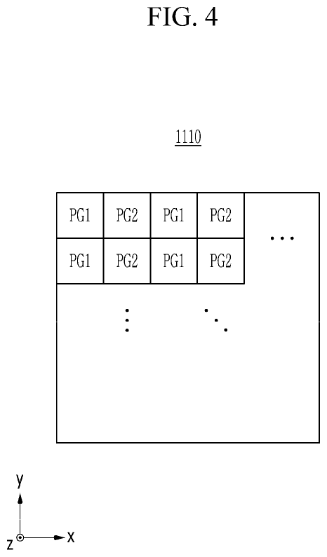

FIG. 4 to FIG. 7 illustrates a top plan view of pixel disposition of a pixel array according to an example embodiment.

As shown in FIG. 4, the pixel array 1110 of the CMOS image sensor 1100 may include a plurality of first and second pixel groups PG1 and PG2 that are repeatedly disposed on the substrate of the image sensor 1000 along an X-axis. In FIG. 4, it is illustrated that all of the first pixel groups PG1 are disposed in the first column, but the present disclosure is not limited thereto, and the second pixel group PG2 may be disposed therein.

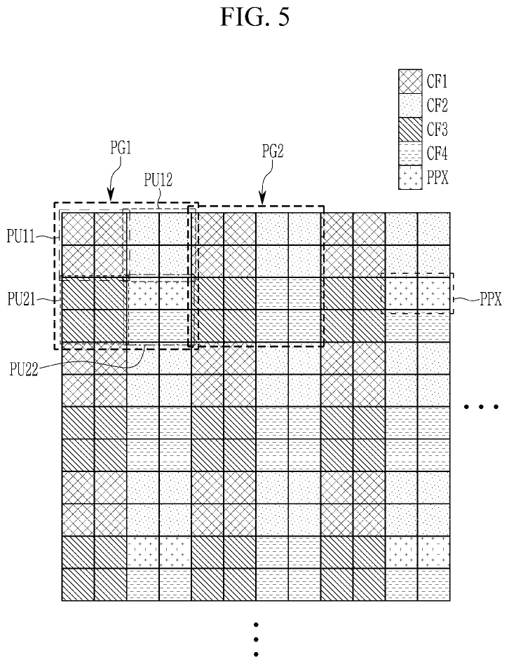

FIG. 5 illustrates pixel dispositions in the first pixel group PG1 and the second pixel group PG2.

As shown in FIG. 5, each pixel group PG1 or PG2 may include a plurality of pixel units. The plurality of pixel units may be disposed in an A×B form (where A and B are both arbitrary natural numbers). Hereinafter, it will be described that one pixel group includes four pixel units, and the four pixel units are disposed in a 2×2 form in one pixel group. For example, the first pixel group PG1 may include 2×2 pixel units (PU11, PU12, PU21, and PU22), but is not limited thereto.

One pixel unit may include pixels for outputting information related to one color. In some example embodiments, the same color filter may be formed on one pixel unit. For example, a first color filter CF1 may be formed on the pixel unit PU11, a second color filter CF2 may be formed on the pixel unit PU12, a third color filter CF3 may be formed on the pixel unit PU21, and a fourth color filter CF4 may be formed on the pixel unit PU22. The first color filter CF1 may transmit green (Gr) light, the second color filter CF2 may transmit red (R) light, the third color filter CF3 may transmit blue (B) light, and the fourth color filter CF4 may transmit green (Gb) light. Hereinafter, a pixel on which the first color filter CF1 is formed is referred to as a first green pixel, a pixel on which the second color filter CF2 is formed is referred to as a red pixel, a pixel on which the third color filter CF3 is formed is referred to as a blue pixel, and a pixel on which the fourth color filter CF4 is formed is referred to as a second green pixel.

The plurality of pixel units PU11, PU12, PU21, and PU22 may be disposed in a Bayer pattern in one pixel group PG1 or PG2. In the present disclosure, for better understanding and ease of description, it is illustrated that as one implementation of the Bayer pattern, the pixel unit PU12 is disposed on the right side of the pixel unit PU11, the pixel unit PU21 is disposed below the pixel unit PU11, and the pixel unit PU22 is disposed on the diagonal side of the pixel unit PU11, but the present disclosure is not limited thereto, and the positions of the pixel units may be exchanged, or instead of one of the pixel units PU11 and PU22 with green pixels, it may be combined with other color configurations such as a pixel unit with white pixels, a pixel unit with yellow pixels, and a pixel unit with cyan pixels.

One pixel group may include a plurality of phase detection pixels PPX. For example, the pixel unit PU22 in the pixel group PG1 may include a plurality of second green pixels and a plurality of phase detection pixels PPX. As another example, one pixel unit PU22 may include only a plurality of phase detection pixels PPX. As a further example, the pixel unit PU22 in the pixel group PG1 may include only a plurality of second green pixels.

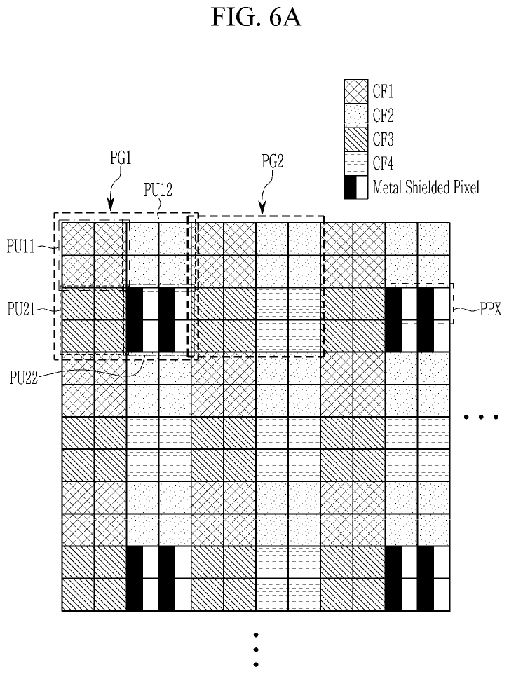

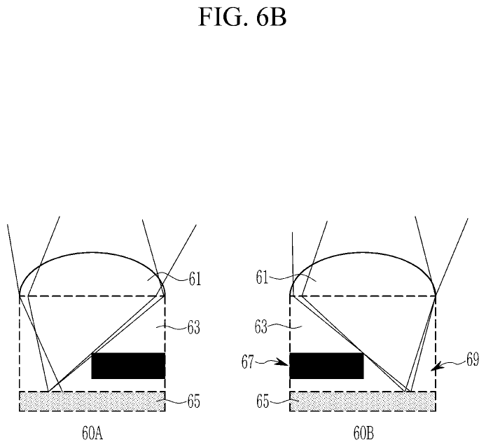

According to the embodiment, as shown in FIG. 6A, the phase detection pixel PPX may be a metal shielded pixel (see PPX in FIG. 6A). The metal shielded pixel is a pixel in which half of the pixel is shielded with a metal thin film and in which there are two types of shielded pixels, a left shielded pixel and a right shielded pixel, and the phase information of the left and right shielded pixels enables phase detection auto focus (PDAF) for high-speed AF by the image signal processor 1300. In the present specification, it is shown that the left shielded pixel and the right shielded pixel are disposed in a 2×2 form, respectively, but the present disclosure is not limited thereto, and in the embodiment, the left shielded pixel and the right shielded pixel may each be disposed adjacent to one pixel.

FIG. 6B is a drawing schematically illustrating a configuration of a metal shielded pixel according to example embodiments.

Referring to FIG. 6B, a first metal shielded pixel 60A may be a left shielded pixel, and a second metal shielded pixel 60B may be a right shielded pixel. The metal shielded pixels 60A and 60B may each include a micro lens 61, a mask layer 63, and a photoelectric conversion device 65.

The mask layer 63 may form a shielded area in the metal shielded pixel 60A or 60B. The mask layer 63 may be implemented as a metal mask, and an opening 69 through which light may be incident and a shielded area 67 through which light may be blocked may be distinguished by the mask layer 63. For example, the mask layer 63 may be include the opening 69 through which light is incident and the shielded area 67 through which light is blocked.

The micro lens 61 may focus the incident light to the center of the metal shield pixel and transmit it to the photoelectric conversion device 65. For example, the micro lens 61 may focus the incident light to the center of the opening 69 of the metal shield pixel.

The photoelectric conversion device 65 may convert an incident optical signal into an electrical signal. The photoelectric conversion device 65 may be, for example, a photodiode or the like.

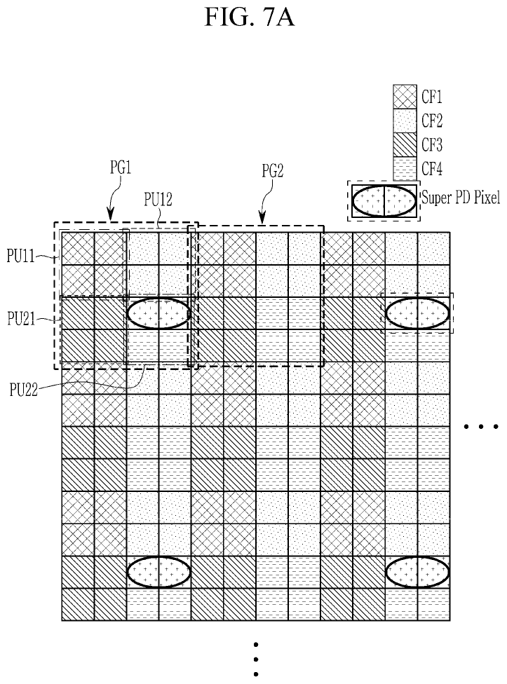

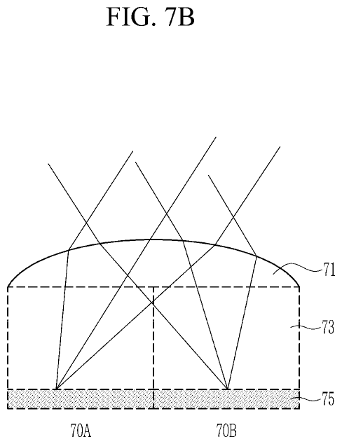

According to another embodiment, as shown in FIG. 7A, the phase detection pixel PPX may be a super PD pixel. The super PD pixel is a pixel in which one microlens is disposed on two adjacent phase detection pixels PPX, and phase information of light incident on the photoelectric conversion device of the super PD pixel enables phase detection auto focus (PDAF) for high-speed AF by the image signal processor 1300.

FIG. 7B is a drawing schematically illustrating a configuration of a super PD pixel according to example embodiments.

A first pixel 70A and a second pixel 70B may each include a mask layer 73 and a photoelectric conversion device 75, and one micro lens 71 may be disposed on the mask layer 73 of the first pixel 70A and the second pixel 70B. Light incident to the micro lens 71 is refracted, and the incident light may form an image on the photoelectric conversion device 75 of the first pixel 70A and the second pixel 70B, respectively. The photoelectric conversion device 75 may be, for example, a photodiode or the like.

In the embodiment, a ratio of the number of phase detection pixels PPX to the number of pixels disposed in the pixel array 1110 may be 1/32. A signal generated by the phase detection pixel PPX may be different from a signal generated by the image sensing pixel IPX. For example, the signal generated by the phase detection pixel PPX may have lower sensitivity than the signal generated by the image sensing pixel IPX. Accordingly, the image signal processor 1300 may prevent image quality degradation by performing bad pixel correction (BPC) on the phase detection pixel PPX.

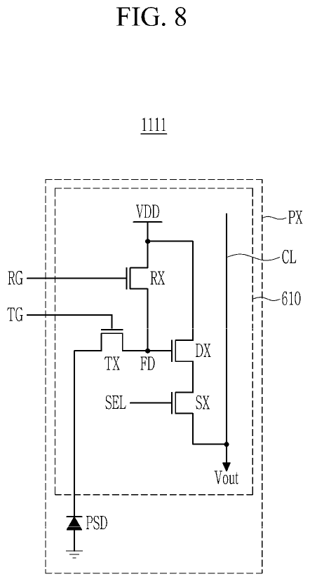

FIG. 8 illustrates a circuit diagram of an example configuration of a pixel according to an example embodiment.

In the embodiment, a pixel 1111 may be the image sensing pixel (IPX) or the phase detection pixel (PPX). It may include a photoelectric conversion device PSD and a CIS pixel circuit 610 having a 4TR structure including four transistors. The pixel 1111 may include the photoelectric conversion device PSD, a transmission transistor TX, a reset transistor RX, a driving transistor DX, and a selection transistor SX. The photoelectric conversion device PSD of FIG. 8 may correspond to the photoelectric conversion device 65 of FIG. 6B or the photoelectric conversion device 75 of FIG. 7B.

In the embodiment, the photoelectric conversion device PSD may generate charges in response to incident light. For example, the photoelectric conversion device PSD may generate a photocurrent by converting an optical signal into an electrical signal. In the embodiment, the transmission transistor TX may receive charges generated by the photoelectric conversion device PSD to transmit them to a floating diffusion area FD. For example, one end of the transmission transistor TX may be connected to the photoelectric conversion device PSD, and the other end thereof may be connected to the floating diffusion area FD. The transmission transistor TX may be turned on or off under the control of a control signal TG received from the row driver 1120 (see FIG. 3).

The floating diffusion area FD has a function of detecting charges corresponding to an amount of incident light. During a time when the control signal TG is activated, the charges provided from the photoelectric conversion device PSD may accumulate in the floating diffusion area FD. The floating diffusion area FD may be connected to a gate terminal of the driving transistor DX driven by a source follower amplifier. The floating diffusion area FD may be reset by a power voltage VDD provided when the reset transistor RX is turned on.

The reset transistor RX may be turned on by a reset signal RG to provide the power voltage VDD to the floating diffusion area FD. As a result, the charges accumulated in the floating diffusion area FD may move to the terminal of the power voltage VDD, and the voltage of the floating diffusion area FD may be reset. Although the power voltage VDD is used as the voltage applied to the floating diffusion area FD, various levels of voltage (e.g., reset voltage) may be used to reset the floating diffusion area FD.

The driving transistor DX may operate as a source follower amplifier. The driving transistor DX may amplify a change in electrical potential of the floating diffusion area FD, and may output an output voltage VOUT corresponding thereto.

The selection transistor SX may be driven by a selection signal SEL to select pixels to be read in units of rows. When the selection transistor SX is turned on, the potential of the floating diffusion area FD is amplified through the driving transistor DX to be transmitted to a drain electrode of the selection transistor SX.

In the embodiment, the signals generated by the pixel 1111 on the first semiconductor die DIE1 (see FIG. 2) may be transmitted to the second semiconductor die DIE2 (see FIG. 2) and/or the third semiconductor die DIE3 (see FIG. 2) through connection structures connected to the first pad PAD1 (see FIG. 2), the second pad PAD2 (see FIG. 2), and/or the third pad PAD3 (see FIG. 2).

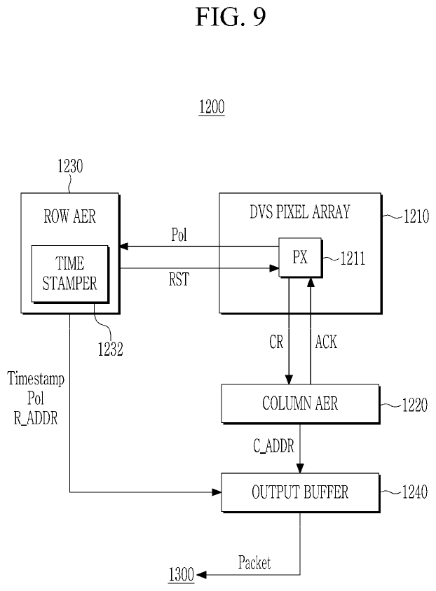

FIG. 9 illustrates an example configuration of a dynamic vision sensor according to example embodiments.

The dynamic vision sensor 1200 may include a DVS pixel array 1210, a column address event representation (AER) circuit 1220, a row AER circuit 1230, and an output buffer 1240. The dynamic vision sensor 1200 may detect an event in which intensity of light is changed (hereinafter, referred to as an ‘event’), may determine a type of the event (for example, whether the intensity of light is increasing or decreasing), and may output a value corresponding to the event. For example, the event may mainly occur in an outline of a moving object. A signal outputted from the dynamic vision sensor 1200 may differ from a signal outputted from the CMOS image sensor (e.g., CMOS image sensor 1100 in FIG. 1). For example, unlike the CMOS image sensor (e.g., CMOS image sensor 1100 in FIG. 1), since the dynamic vision sensor 1200 outputs only a value corresponding to light whose intensity changes, the amount of data processed by the dynamic vision sensor 1200 and/or the image signal processor (e.g., image signal processor 1300 in FIG. 1) may be significantly reduced.

The DVS pixel array 1210 may include a plurality of DVS pixels PX arranged in a matrix format along a plurality of rows and a plurality of columns. A DVS pixel 1211, which may be one of the plurality of DVS pixels PX, detecting an event among the plurality of pixels configuring the DVS pixel array 1210 may transmit a column request CR signal indicating that an event in which light intensity increases or decreases has occurred to the column AER circuit 1220.

The column AER circuit 1220 may transmit a response signal ACK to the pixel in response to the column request CR received from the pixel sensing the event. The pixel receiving the response signal ACK may transmit polarity information Pol of the generated event to the row AER circuit 1230. The column AER circuit 1220 may generate a column address C_ADDR of the pixel that senses the event based on the column request CR received from the pixel that senses the event.

The row AER circuit 1230 may receive the polarity information Pol from the pixel that senses the event. The row AER circuit 1230 may generate a timestamp including information about a time when an event occurred based on the polarity information Pol. For example, the timestamp may be generated by a time stamper 1232 provided in the row AER circuit 1230. For example, the time stamper 1232 may be implemented using a time tick generated in units of several to several tens of microseconds. The row AER circuit 1230 may transmit a reset signal RST to the DVS pixel 1211 in which an event occurred in response to the polarity information Pol. The reset signal RST may reset the DVS pixel 1211 in which an event occurred. Furthermore, the row AER circuit 1230 may generate a row address R_ADDR of the DVS pixel 1211 in which an event occurred. The row AER circuit 1230 may transmit the timestamp, the polarity information Pol, and the row address R_ADDR to the output buffer 1240.

The row AER circuit 1230 may control a period in which the reset signal RST is generated. For example, the row AER circuit 1230 may control a period in which the reset signal RST is generated so that no events occur during a specific period in order to prevent an increase in workload due to excessive events. That is, the row AER circuit 1230 may control a refractory period of event generation.

The output buffer 1240 may generate a packet based on the timestamp, the column address C_ADDR, the row address R_ADDR, and the polarity information Pol. The output buffer 1240 may add a header indicating the start of the packet to the front end of the packet and a tail indicating the end of the packet to the rear end of the packet.

In the embodiment, at least some of the column AER circuit 1220, the row AER circuit 1230, and the output buffer 1240 described above may be the DVS logic (e.g., DVS logic 2112 in FIG. 2).

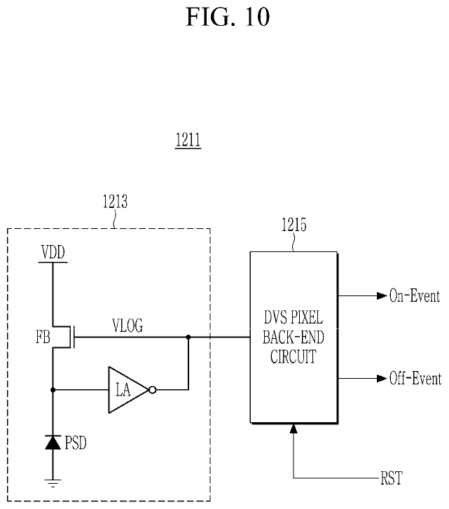

FIG. 10 illustrates a circuit diagram of an example configuration of a DVS pixel that configures a pixel array of a dynamic vision sensor according to example embodiments. The DVS pixel 1211 includes a photoreceptor 1213 and a DVS pixel back-end circuit 1215.

The photoreceptor 1213 may include a photoelectric conversion device PSD, a logarithmic amplifier LA, and a feedback transistor FB. The log amplifier LA may output a log voltage VLOG of a log scale by amplifying a voltage corresponding to a photocurrent generated by the photoelectric conversion device PSD. The feedback transistor FB may transmit a log voltage to the DVS pixel back-end circuit 1215 based on the log voltage.

The DVS pixel back-end circuit 1215 may perform various processing on the log voltage VLOG. In the embodiment, the DVS pixel back-end circuit 1215 may amplify the log voltage VLOG, may compare the amplified voltage with a reference voltage to determine whether the light incident to the photoelectric conversion device PSD is light whose intensity increases or decreases, and may output an event signal (that is, on-event or off-event) corresponding to the determined value. An event signal outputted from the DVS pixel back-end circuit 1215 may be polarity information (e.g., polarity information Pol in FIG. 9). After the DVS pixel back-end circuit 1215 outputs the event signal (that is, on-event or off-event), the DVS pixel back-end circuit 1215 may be reset by the reset signal RST.

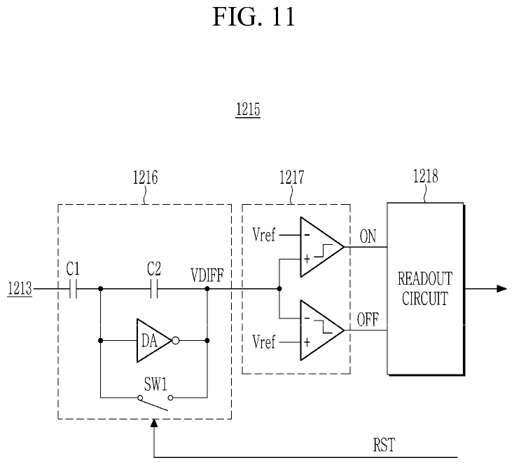

FIG. 11 illustrates an example configuration of a back-end circuit of a dynamic vision sensor pixel according to example embodiments. The DVS pixel back-end circuit 1215 may include a differentiator 1216, a comparator 1217, and an output logic circuit 1218.

The differentiator 1216 may be configured to amplify a voltage VLOG received from photoreceptor 1213 to generate a voltage VDIFF. For example, the differentiator 1216 may include capacitors C1 and C2, a differential amplifier DA, and a switch SW operated by a reset signal RST. For example, the capacitors C1 and C2 may store electrical energy generated by at least one photoelectric conversion device PSD. For example, capacitances of the capacitors C1 and C2 may be appropriately selected considering the shortest time between two events that may occur consecutively in one pixel (e.g., refractory period). When the switch SW is switched-on by the reset signal RST, the pixel may be initialized. The reset signal RST may be received from the row AER circuit (e.g., row AER circuit 1230 in FIG. 9).

The comparator 1217 may compare the output voltage VDIFF of the differential amplifier DA and the reference voltage Vref to determine whether an event sensed from the pixel is an on-event or an off-event. When an event of increasing light intensity is detected, the comparator 1217 may output a signal (ON) indicating an on-event, and when an event of decreasing light intensity is detected, the comparator 1217 may output a signal (OFF) indicating an off-event.

The output logic circuit 1218 may transmit information on an event generated in the pixel. The information outputted from the output logic circuit 1218 may include information (for example, bits) on whether the generated event is an on-event or an off-event. The information on the event outputted from the output logic circuit 1218 may be the polarity information (e.g., polarity information Pol in FIG. 9). The polarity information may be transmitted to the row AER circuit (e.g., row AER circuit 1230 in FIG. 9).

In the embodiment, the signal generated by the DVS pixel 1211 may be transmitted to the third semiconductor die (e.g., third semiconductor die DIE3 in FIG. 2) through connection structures connected to the second pad (e.g., second pad PAD2 in FIG. 2) and the third pad (e.g., third pad PAD3 in FIG. 2).

Meanwhile, the configuration of the pixel shown in the present embodiment is an example, and the present disclosure will be applied to DVS pixels of various configurations configured to determine the type of an event by detecting the changing light intensity.

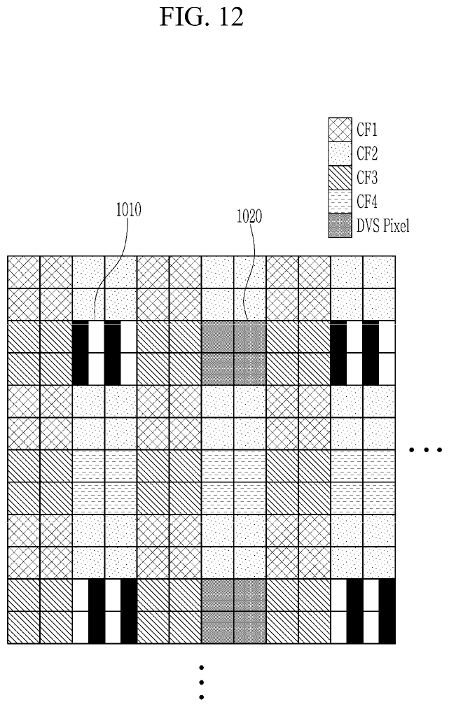

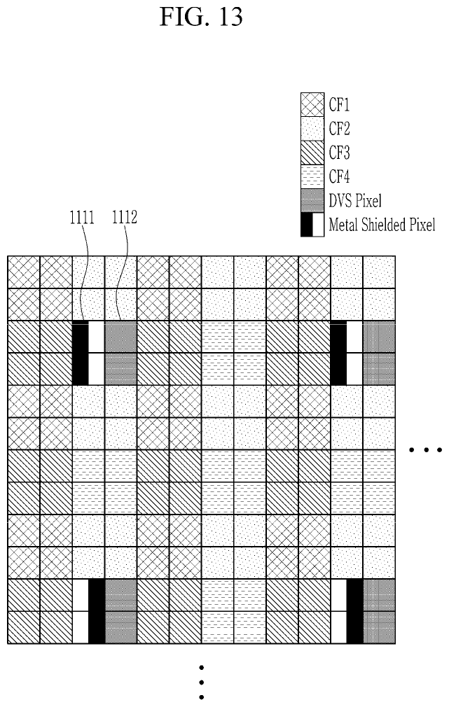

FIG. 12 and FIG. 13 illustrate top plan views of pixel disposition including a phase detection pixel and a dynamic vision sensor pixel according to an example embodiment.

FIG. 12 illustrates a pixel disposition of the pixel array area (e.g., pixel array area 2100 in FIG. 2) of the first semiconductor die DIE1 of the image sensor including the image sensing pixels IPX, the phase detection pixels PPX, and the DVS pixels. According to the embodiment, the phase detection pixels PPX may be metal shielded pixels 1010. In order to provide the phase detection pixels PPX and the DVS pixels that provide the phase detection auto focus (PDAF) function as one image sensor, dynamic vision sensor (DVS) pixels 1020 may be additionally disposed in the pixel array including the metal shielded pixels 1010. However, in this structure, since some of the image sensing pixels IPX are replaced with the DVS pixels 1020, the image signal processor 1300 additionally requires processing such as the bad pixel correction (BPC) for the DVS pixels 1020 as well as the metal shielded pixels 1010. This may put a burden on the BPC algorithm of the image signal processor 1300.

FIG. 13 illustrates a top plan view of a pixel disposition in which some of the metal shielded pixels, which are a type of phase detection pixel PPX, are replaced with DVS pixels 1112 according to an example embodiment. Alternatively, it may be a pixel disposition in which some of the DVS pixels 1112 are replaced with the metal shielded pixels, which are a type of phase detection pixel PPX. In the embodiment, since some of the metal shielded pixels are replaced with the DVS pixels 1112, a ratio of the number of the metal shielded pixels 1111 and the DVS pixels 1112 to the number of the plurality of pixels may be maintained the same as before (for example, 1/32). Accordingly, the burden on the BPC algorithm of the image signal processor 1300 for processing the BPC for the metal shielded pixel 1111 and the DVS pixel 1112 may be reduced.

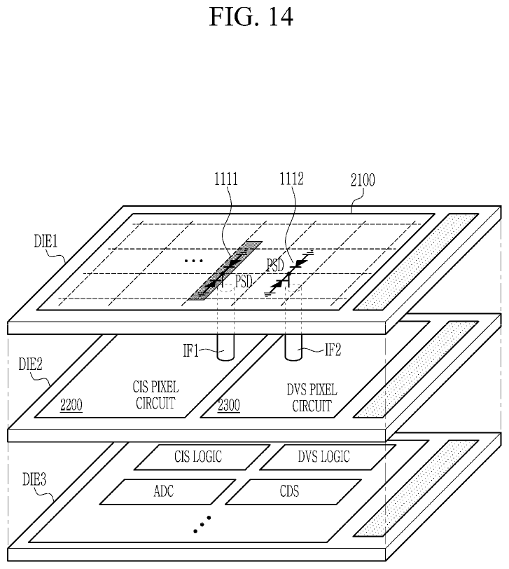

FIG. 14 illustrates a perspective view of an image sensor including a phase detection pixel and a DVS pixel according to an example embodiment. Here, the configuration of each die of the image sensor when the phase detection pixel and the DVS pixel are included in one device will be described.

In the embodiment, the first semiconductor die DIE1 may include the pixel array area 2100, and a plurality of image sensing pixels IPX may be disposed in the pixel array. The image sensing pixels IPX may include the photoelectric conversion device PSD and the CIS pixel circuit (e.g., CIS pixel circuit 610 in FIG. 8). In the embodiment, a metal shielded pixel 1111 and a DVS pixel 1112 may be further disposed in the pixel array area 2100. In the embodiment, the photoelectric conversion device PSD of the metal shielded pixel 1111 and the photoelectric conversion device PSD of the DVS pixel 1112 may be disposed in the pixel array of the first semiconductor die DIE1. In the embodiment, the photoelectric conversion devices PSD of the metal shielded pixel 1111 and the DVS pixel 1112 may be connected to the CIS pixel circuit 2200 and the DVS pixel circuit 2300 of the second semiconductor die DIE2 through the first connection structure IF1 and the second connection structure IF2, respectively. Charges generated by the photoelectric conversion devices PSD may be transmitted to the CIS pixel circuit 2200 and the DVS pixel circuit 2300 through the first connection structure IF1 and the second connection structure IF2, respectively. In the embodiment, the first and second connection structures IF1 and IF2 may mean various configurations for electrically connecting the photoelectric conversion devices PSD and the CIS pixel circuit 2200 and the DVS pixel circuit 2300. For example, the first and second connection structures IF1 and IF2 may include at least one of an electrical line, a wire, a solder ball, a bump, and a through silicon via (TSV). In the embodiment, the first connection structure IF1 may be disposed in an area in which the pixel array area 2100 in which the photoelectric conversion device PSD is disposed and overlaps the CIS pixel circuit 2200, and the second connection structure IF2 may be disposed in an area in which the pixel array area 2100 in which the photoelectric conversion device PSD is disposed and overlaps the DVS pixel circuit 2300.

In the embodiment, the CIS pixel circuit 2200 and the DVS pixel circuit 2300 of the second semiconductor die DIE2 may receive charges from the first semiconductor die DIE1 to generate an output signal. The output signal generated by the first semiconductor die DIE1 and/or the second semiconductor die DIE2 may be transmitted to the third semiconductor die DIE3 through connection structures connected to the first pad PAD1, the second pad PAD2, and/or the third pad PAD3.

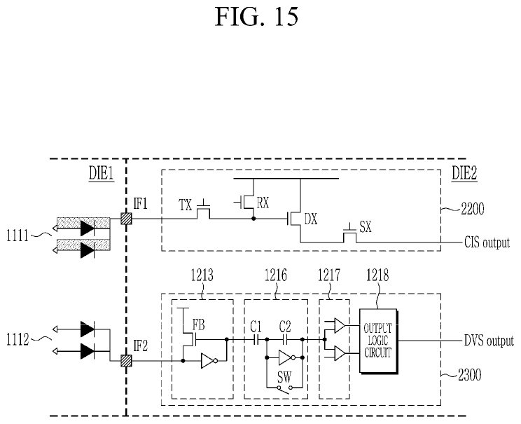

FIG. 15 illustrates a circuit diagram of an example configuration of a portion of an image sensor according to an example embodiment. Specifically, FIG. 15 illustrates a circuit diagram of a structure in which the photoelectric conversion devices PSD of the metal shielded pixel 1111 and the DVS pixel 1112 of the first semiconductor die DIE1 are connected to the CIS pixel circuit 2200 and the DVS pixel circuit 2300 of the second semiconductor die DIE2. The left side of FIG. 15 illustrates the photoelectric conversion device PSD of the metal shielded pixel 1111 and the photoelectric conversion device PSD of the DVS pixel 1112 of the first semiconductor die DIE1 of FIG. 14, and the right side of FIG. 15 illustrates the CIS pixel circuit 2200 and the DVS pixel circuit 2300 of the second semiconductor die DIE2 of FIG. 14.

In the embodiment, the charge generated by the photoelectric conversion device PSD of the metal shielded pixel 1111 of the first semiconductor die DIE1 may be transmitted to the CIS pixel circuit 2200 through the first connection structure IF1, and the charge generated by the photoelectric conversion device PSD of the DVS pixel 1112 may be transmitted to the DVS pixel circuit 2300 through the second connection structure IF2.

Here, the metal shielded pixel 1111 is illustrated as a left shielded pixel, but is not limited thereto, and the metal shielded pixel 1111 may be a right shielded pixel.

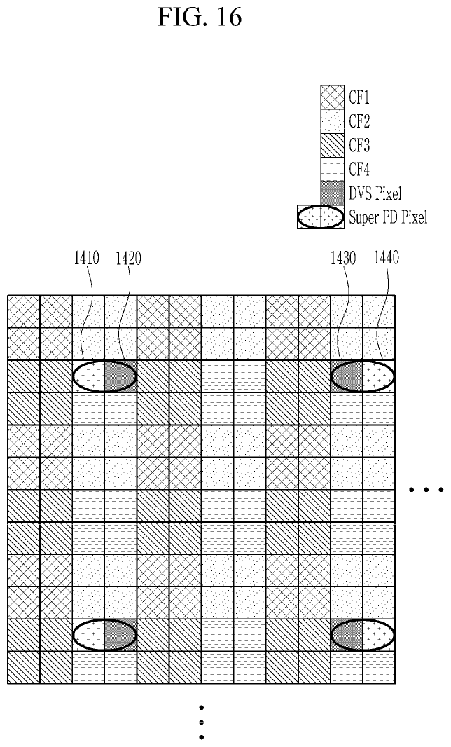

FIG. 16 illustrates a top plan view of a pixel disposition in which some of the super PD pixels, which are a type of phase detection pixel PPX, are replaced with the DVS pixels 1420 and 1430 according to an example embodiment. Since some of the super PD pixels are replaced with the DVS pixels 1420 and 1430, a ratio of the number of phase detection pixels 1410 and 1440 and DVS pixels 1420 and 1430 to the number of the plurality of pixels may be maintained the same as before (for example, 1/32). Accordingly, the burden on the BPC algorithm of the image signal processor 1300 for BPC processing of the phase detection pixels 1410 and 1440 and the DVS pixels 1420 and 1430 may be reduced.

In the embodiment, when the phase detection pixels 1410 and 1440 and the DVS pixels 1420 and 1430 are disposed, the phase detection pixel 1410 and DVS pixel 1420 and the DVS pixel 1430 and phase detection pixel 1440 may be alternately disposed. Accordingly, the phase detection pixels 1410 and 1440 may configure a pair of super PD pixels.

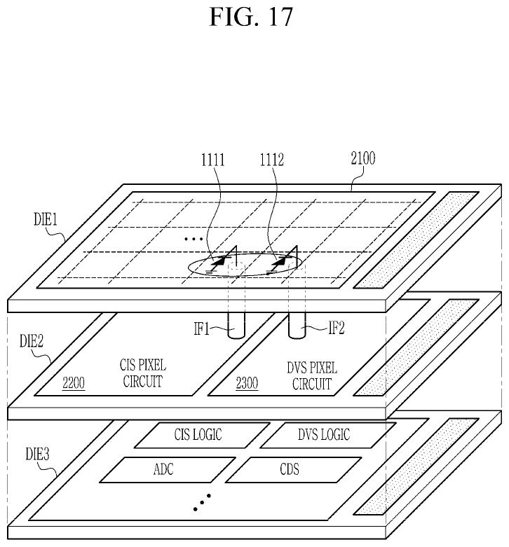

FIG. 17 illustrates a perspective view of an image sensor including a phase detection pixel and a dynamic vision sensor pixel according to an example embodiment. Here, in order to simultaneously implement a CMOS image sensor and a dynamic vision sensor in one device, a configuration of each die of an image sensor when a phase detection pixel and a DVS pixel are included in a CMOS image sensor will be described.

In the embodiment, the first semiconductor die DIE1 may include the pixel array area 2100, and a plurality of image sensing pixels IPX may be disposed in the pixel array area 2100. The image sensing pixel IPX may include the photoelectric conversion device PSD and the CIS pixel circuit (e.g., CIS pixel circuit 610 in FIG. 8). In the embodiment, a phase detection pixel 1410 and a DVS pixel 1420 may be further disposed in the pixel array area 2100. In the embodiment, the photoelectric conversion devices PSD of the phase detection pixel 1410 and the DVS pixel 1420 may be disposed in the pixel array area 2100 of the first semiconductor die DIE1. In the embodiment, the photoelectric conversion devices PSD of the phase detection pixel 1410 and the DVS pixel 1420 may be connected to the CIS pixel circuit 2200 and the DVS pixel circuit 2300 of the second semiconductor die DIE2 through the first connection structure IF1 and the second connection structure IF2, respectively. In the embodiment, the first connection structure IF1 may be disposed in an area of the pixel array area 2100 in which the photoelectric conversion device PSD is disposed and the CIS pixel circuit 2200 overlap, and the second connection structure IF2 may be disposed in an area of the pixel array area 2100 in which the photoelectric conversion device PSD is disposed and the DVS pixel circuit 2300 overlap. The connection structure of the first semiconductor die DIE1 and the second semiconductor die DIE2 is the same as that of FIG. 14, so a detailed description thereof will be omitted.

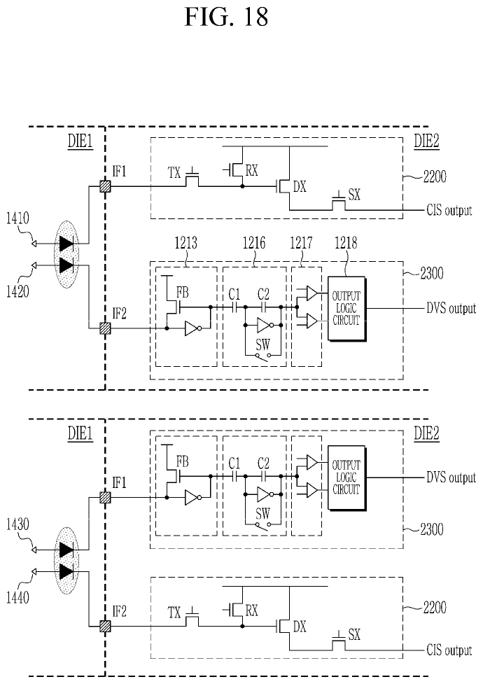

FIG. 18 illustrates a circuit diagram of an example configuration of a portion of an image sensor according to an example embodiment.

In the embodiment, the photoelectric conversion devices PSD of the phase detection pixel 1410 and the DVS pixel 1420 of the first semiconductor die DIE1 may be respectively connected to the CIS pixel circuit 2200 and the DVS pixel circuit 2300 disposed on the second semiconductor die DIE2 through the first and second connection structures IF1 and IF2 connected to the first semiconductor die DIE1 and the second semiconductor die DIE2. As described above, the phase detection pixel 1410 and DVS pixel 1420 and the DVS pixel 1430 and phase detection pixel 1440 may be alternately disposed, and the phase detection pixels 1410 and 1440 may configure a pair of super PD pixels.

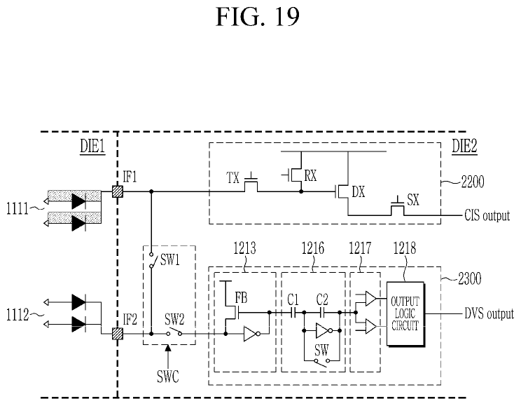

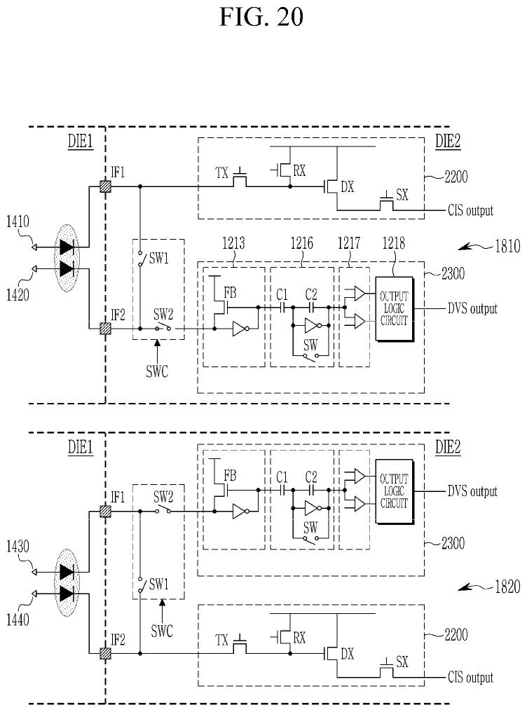

FIG. 19 and FIG. 20 illustrate circuit diagrams of an example configuration of a portion of an image sensor according to an example embodiment.

In the embodiment, the second semiconductor die DIE2 may further include a configuration for changing the connection relationship (for example, first and second switches SW1 and SW2) between the phase detection pixel PPX and the photoelectric conversion device PSD of the DVS pixel and the CIS pixel circuit 2200 and the DVS pixel circuit 2300 on the second semiconductor die DIE2. The first and second switches SW1 and SW2 may be controlled by a switch control signal SWC generated by the image signal processor 1300 or the row AER (e.g., row AER circuit 1230 in FIG. 9).

Referring to FIG. 19, in the embodiment, when the first switch SW1 is switched-off and the second switch SW2 is switched-on, the CMOS image sensor (e.g., CMOS image sensor 1100) and the dynamic vision sensor (e.g., dynamic vision sensor 1200) may separately operate. In the embodiment, when the first switch SW1 is switched-on and the second switch SW2 is switched-off, the photoelectric devices PSD of the DVS pixels 1112 disposed in the first semiconductor die DIE1 are all connected to the CIS pixel circuit 2200, so that the image sensor 1000 may operate as a CMOS image sensor (e.g., CMOS image sensor 1100). In the embodiment, in a state in which the first switch SW1 is switched-on, the second switch SW2 is switched-on, and the control signal TG of the transmission transistor TX is off, all of the photoelectric conversion devices PSD of the metal shielded pixels 1111 disposed on the first semiconductor die DIE1 may be connected to the DVS pixel circuit 2300.

Referring to FIG. 20, in the embodiment, when the first switch SW1 is switched-off and the second switch SW2 is switched-on, the CMOS image sensor (e.g., CMOS image sensor 1100) and the dynamic vision sensor (e.g., dynamic vision sensor 1200) may separately operate. That is, the phase detection pixels 1410 and 1440 may configure a pair of super PD pixels, and the DVS pixels 1420 and 1430 may operate as separate dynamic vision sensors. In the embodiment, when the first switch SW1 is switched-on and the second switch SW2 is switched-off, the photoelectric conversion devices PSD of the DVS pixels 1420 and 1430 disposed on the first semiconductor die DIE1 are all connected to the CIS pixel circuit 2200, so that each of the first pixel 1810 and the second pixel 1820 may configure a separate super PD pixel to operate as a CMOS image sensor. In the embodiment, in a state in which the first switch SW1 is switched-on, the second switch SW2 is switched-on, and the control signal TG of the transmission transistor TX is off, all of the photoelectric conversion devices PSD of the phase detection pixels 1410 and 1440 disposed on the first semiconductor die DIE1 may be connected to the DVS pixels 1420 and 1430.

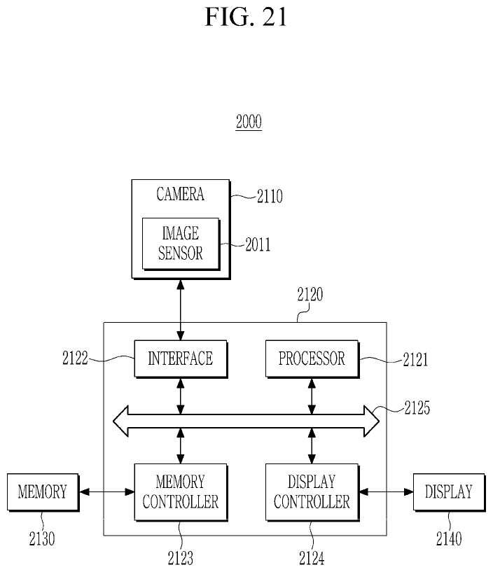

FIG. 21 illustrates a block diagram of a computing device according to an example embodiment.

Referring to FIG. 21, a computing device 2000 may include a camera 2110, a controller 2120, a memory 2130, and a display 2140.

The camera 2110 may include an image sensor 2011. The image sensor 2011 may be implemented as the image sensor 1000 described with reference to FIG. 1 to FIG. 20. In the embodiment, the image sensor 2011 may be an image sensor in which the phase detection pixels and the DVS pixels are included. In the embodiment, a structure in which the DVS pixel circuit and the pixel circuit for the phase detection are formed on the semiconductor die that is different from the image sensing pixel may optimize the size of the image sensor. In the embodiment, as the number of the phase detection pixels and the DVS pixels for the image sensing pixels satisfies a predetermined ratio (e.g., 1/32), the load on the BPC algorithm of the image sensor processor may be reduced. The camera 2110 may generate an image signal by using the image sensor 2011, may perform image signal processing on the image signal, and may output the processed image signal to the controller 2120.

The controller 2120 may include a processor 2121. The processor 2121 may control an overall operation of each constituent element of the computing device 2000. The processor 2121 may be implemented as at least one of various processing units such as a central processing unit (CPU), an application processor (AP), and a graphic processing unit (GPU). In some embodiments, the controller 2120 may be implemented as an integrated circuit or a system on chip (SoC).

In the embodiment, as shown in FIG. 21, the controller 2120 may further include an interface 2122, a memory controller 2123, a display controller 2124, and a bus 2125. In some embodiments, at least some of the interface 2122, the memory controller 2123, the display controller 2124, and the bus 2125 may be provided outside the controller 2120. In some embodiments, the controller 2120 may further include an image signal processor.

The interface 2122 may transmit an image signal received from the image sensor 2011 to the memory controller 2123 or the display controller 2124 through the bus 2125.

The memory 2130 may store various data and commands. The memory controller 2123 may control transmission of data or instructions to and from the memory 2130.

The display controller 2124 may transmit data to be displayed on the display 2140 to the display 2140 under control of the processor 2121, and the display 2140 may display a screen based on the received data. In some embodiments, the display 2140 may further include a touch screen. The touch screen may transmit a user input capable of controlling an operation of the computing device 2000 to the controller 2120. The user input may be generated when a user touches the touch screen.

The bus 2125 may provide a communication function between constituent elements of the controller 2120. The bus 2125 may include at least one type of bus according to a communication protocol between the constituent elements.

While the embodiment of the present disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. An image sensor comprising:
a first die including a pixel array area in which first and second photoelectric conversion devices configured to generate respective charges corresponding to incident light are disposed; and
a second die including a first pixel circuit configured to receive the charges from the first photoelectric conversion device and generate a phase signal of the incident light based on the charges received from the first photoelectric conversion device, and a second pixel circuit configured to receive the charges from the second photoelectric conversion device and generate an event signal corresponding to the incident light based on the charges received from the second photoelectric conversion device.

2. The image sensor of claim 1, further comprising:
a third die including a first logic circuit configured to receive the phase signal from the first pixel circuit, a second logic circuit configured to receive the event signal from the second pixel circuit, and an image signal processor (ISP) configured to receive data outputted from the first logic circuit and the second logic circuit.

3. The image sensor of claim 2, further comprising:
a first pad disposed on the first die to be spaced apart from the pixel array area;
a second pad disposed on the second die to be spaced apart from the first pixel circuit and the second pixel circuit; and
a third pad disposed on the third die to be spaced apart from the first logic circuit, the second logic circuit, and the image signal processor.

4. The image sensor of claim 3, wherein the first pad is electrically connected to the second pad, and the second pad is electrically connected to the third pad.

5. The image sensor of claim 3, wherein a third photoelectric conversion device configured to generate charges corresponding to incident light and a third pixel circuit configured to receive the charges from the third photoelectric conversion device to generate an output voltage are further disposed in the pixel array area.

6. The image sensor of claim 5, wherein the third pixel circuit is connected to the first pad through a metal layer on the first die.

7. The image sensor of claim 5, wherein the number of the first photoelectric conversion devices and the second photoelectric conversion devices with respect to the number of the third photoelectric conversion devices in the pixel array area satisfies a predetermined ratio.

8. The image sensor of claim 1, further comprising:
a first connection structure configured to connect the first photoelectric conversion device and the first pixel circuit and disposed in an area in which the pixel array area and the first pixel circuit overlap; and
a second connection structure configured to connect the second photoelectric conversion device and the second pixel circuit and disposed in an area in which the pixel array area and the second pixel circuit overlap.

9. The image sensor of claim 8, further comprising:
a first switch including one end electrically connected to the second connection structure and the other end electrically connected to the second pixel circuit; and
a second switch including one end electrically connected between the first connection structure and the first pixel circuit and the other end electrically connected to one end of the first switch.

10. The image sensor of claim 9, wherein the first switch and the second switch are disposed on the second die.

11. The image sensor of claim 8, wherein the first connection structure and the second connection structure are at least one of an electrical line, a wire, a solder ball, a bump, and a through silicon via (TSV).

12. The image sensor of claim 1,
wherein the first photoelectric conversion device and the second photoelectric conversion device are disposed adjacent to each other, and
wherein one micro lens disposed on the first photoelectric conversion device and the second photoelectric conversion device is further included.

13. The image sensor of claim 1, further comprising:
a mask layer disposed on the first photoelectric conversion device and of which a first or second side is shielded.

14. An image sensor comprising:
a phase detection pixel including a first photoelectric conversion device configured to generate charges corresponding to incident light, and a first pixel circuit configured to generate an output voltage corresponding to the charges received from the first photoelectric conversion device and a phase signal of the incident light; and
a dynamic vision sensor (DVS) pixel including a second photoelectric conversion device configured to generate charges corresponding to incident light, and a second pixel circuit configured to generate an event signal by detecting a change in intensity of the incident light based on the charges received from the second photoelectric conversion device.

15. The image sensor of claim 14, further comprising:
a first logic circuit configured to receive the phase signal from the first pixel circuit;
a second logic circuit configured to receive the event signal from the second pixel circuit; and
an image signal processor (ISP) configured to receive data output from the first logic circuit and the second logic circuit.

16. The image sensor of claim 15, wherein the image signal processor generates a signal that controls:
a first mode in which the first photoelectric conversion device is connected to the first pixel circuit and the second photoelectric conversion device is connected to the second pixel circuit,
a second mode in which the first photoelectric conversion device is connected to the second pixel circuit, and
a third mode in which the second photoelectric conversion device is connected to the first pixel circuit.

17. The image sensor of claim 16, further comprising:
a first switch disposed between the second photoelectric conversion device and the second pixel circuit and including one end electrically connected to the second photoelectric conversion device and the other end electrically connected to the second pixel circuit; and
a second switch including one end electrically connected between the first photoelectric conversion device and the first pixel circuit and the other end electrically connected to one end of the first switch,
wherein the image signal processor switches on the first switch and switches off the second switch in the first mode,
wherein the image signal processor switches on the first switch and switches on the second switch in the second mode, and
wherein the image signal processor switches off the first switch and switches on the second switch in the third mode.

18. The image sensor of claim 14, wherein the first photoelectric conversion device and the second photoelectric conversion device are disposed on a semiconductor die different from a semiconductor die on which the first pixel circuit and the second pixel circuit are disposed.

19. The image sensor of claim 14, wherein the first pixel circuit and the second pixel circuit are disposed on the same semiconductor die.

20. An image sensor comprising:
a first semiconductor die including a first photoelectric conversion device and a second photoelectric conversion device that convert an optical signal into an electrical signal; and
a second semiconductor die that includes:
a first pixel circuit that includes a first transistor transmitting the electrical signal received from the first photoelectric conversion device to a floating diffusion node, a second transistor having a gate electrode connected to the floating diffusion node, a third transistor resetting the floating diffusion node; and
a second pixel circuit that includes an output logic circuit generating an event signal by detecting a change in intensity of an optical signal based on the electrical signal received from the second photoelectric conversion device.
